(19) United States
(12) Patent Application Publication
(10) Pub. No.: US 2012/0136196 A1
(43) Pub. Date: May 31, 2012

(54) MOBILE IMAGING UNIT WITH ENVIRONMENTAL CONTAINMENT

(75) Inventors: David L. Foxall, Mentor, OH (US); Daniel Lamb, Shaker Heights, OH (US)

(73) Assignee: KONINKLIJKE PHILIPS ELECTRONICS N.V., EINDHOVEN (NL)

(21) Appl. No.: 13/322,577

(22) PCT Filed: May 12, 2010
(86) PCT No.: PCT/IB2010/052124

§ 371 Date: Nov. 28, 2011

Related U.S. Application Data
(60) Provisional application No. 61/218,086, filed on Jun. 18, 2009.

(51) Int. Cl. A61G 10/00; G01R 33/44; H01J 37/20; G06K 9/00

(52) U.S. Cl. 600/21; 382/131; 324/318; 250/455.11

(57) ABSTRACT

A system comprises: an isolation tube (42, 82) extending into a clean area (14), the isolation tube having a closed end (44) and an opposite open end (46) that is open to a contamination area (12) adjacent the clean area in order to receive an imaging subject from the contamination area; and an imaging apparatus (40, 80) disposed in the clean area and movable along the isolation tube in order to image a subject in the isolation tube at a plurality of different positions along the isolation tube. In some more specific embodiments, the system further includes a vehicle (10) having an interior including the contamination area (12) and the adjacent clean area (14) wherein the system is a mobile imaging unit.

The following relates to the medical arts, medical diagnostic arts, epidemic or pandemic containment arts, emergency response arts, public safety arts, hazardous materials (hazmat) arts, and related arts.

The public safety response to a hazardous situation such as an outbreak of a biological pathogen, a release of toxic material, or so forth may include containment or quarantine of the affected persons and area, providing medical assistance for the affected persons, identification of the pathogen or toxic material, acquiring information such as its source, transmission pathway, the current extent of the affected area, and taking remedial measures such as decontamination and cleanup of the affected area.

Medical imaging techniques such as magnetic resonance (MR) imaging, transmission computed tomography (CT) imaging, positron emission tomography (PET) imaging, single photon emission computed tomography (SPECT) imaging, fluoroscopic imaging, or so forth are potential tools for diagnosing and monitoring persons who have (or are suspected to have) been exposed to the health hazard. However, the potential for biological or chemical contamination of the medical imaging apparatus is problematic, since medical imaging systems are complex and not readily decontaminated, and are generally too expensive to be treated as disposable items.

A known approach includes an arrangement in which the (possibly) contaminated or infected subject is disposed in a chemically or biologically contaminated area, the imaging apparatus is disposed in an adjacent clean area, and a subject transfer tube extends from the contaminated area into the clean area so as to coincide with the imaging region of the imaging apparatus. The (possibly) contaminated or infected subject is inserted into the tube and thence into the imaging region for medical imaging. The tube provides an isolating barrier between the (possibly) contaminated or infected subject and the clean area. For mobility, such a system can be disposed in a truck or other vehicle having a trailer partitioned to define an exposed contamination area and an isolated clean area. In a variant system, the subject is sealed in a container sized to fit into the imaging region of the imaging apparatus, the sealed container is transferred via one or more airlocks from the contamination area into the clean area while undergoing external decontamination or cleanup, and the transferred decontaminated sealed container is loaded in the imaging region for imaging.

Such systems and variants thereof are disclosed, for example, in: Love et al., U.S. Publ. Appl. No. 2008/0300479 A1 which is incorporated herein by reference in its entirety; McKnight et al., U.S. Publ. Appl. No. 2008/0171935 A1 which is incorporated herein by reference in its entirety; Wang et al., U.S. Publ. Appl. No. 2008/0173218 A1 which is incorporated herein by reference in its entirety; Francesangeli et al., U.S. Publ. Appl. No. 2008/0177171 A1 which is incorporated herein by reference in its entirety; and Ambrosia et al., Int'l. Appl. No. WO 2009/037606 A1 which is incorporated herein by reference in its entirety.

These systems provide substantial improvements including allowing a contaminated or infected subject to be imaged without contaminating the imaging apparatus, and in the case of a mobile system mounted on a truck or other vehicle enabling such imaging to be performed “on site”, that is, at or near the location of the biological pathogen outbreak or toxic material release.

Some further improvements in mobile imaging units are disclosed herein, such as approaches for facilitating whole-body scanning using an arrangement that facilitates decontamination and cleanup of the contaminated area of the mobile imaging unit. These approaches reduce the workload for hazmat workers operating in the contaminated area generally and in the contaminated area of the mobile imaging unit in particular, and improve coupling between the contaminated area of the mobile imaging unit and the contaminated site.

The following provides new and improved apparatuses and methods which overcome the above-referenced problems and others.

In accordance with one disclosed aspect, a system comprises: an isolation tube extending into a clean area, the isolation tube having a closed end and an opposite open end that is open to a contamination area adjacent the clean area in order to receive an imaging subject from the contamination area; and an imaging apparatus disposed in the clean area and movable along the isolation tube in order to image a subject in the isolation tube at a plurality of different positions along the isolation tube. In some more specific embodiments, the system further includes a vehicle having an interior including the contamination area and the adjacent clean area wherein the system is a mobile imaging unit.

In accordance with another disclosed aspect, an imaging method is disclosed, which is performed using a system including an isolation tube extending into a clean area and having a closed end and an opposite open end that is open to a contamination area adjacent the clean area, and an imaging apparatus disposed in the clean area and movable along the isolation tube, the imaging method comprising: transferring a subject from the contamination area into the isolation tube via the open end of the isolation tube; acquiring imaging data of the subject using the imaging apparatus with the imaging apparatus positioned at a plurality of successive different positions along the isolation tube; and reconstructing the imaging data of the subject to generate one or more reconstructed images of the subject.

One advantage resides in providing a mobile imaging unit that is easier to decontaminate.

Another advantage resides in providing a mobile imaging unit capable of performing whole-body scanning

### Further advantages will be apparent to those of ordinary skill in the art upon reading and understand the following detailed description.

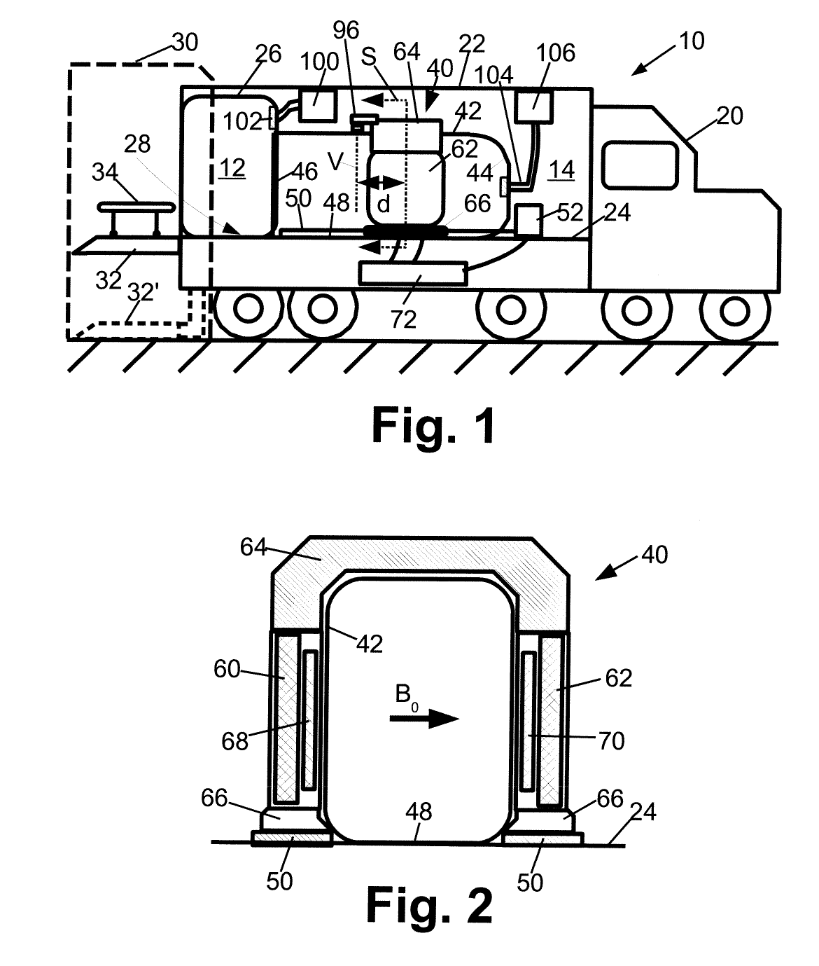

FIG. 1 diagrammatically shows a mobile imaging unit.

FIG. 2 diagrammatically shows a sectional view of the isolation tube and the imaging apparatus of FIG. 1 embodied as a magnetic resonance (MR) scanner, viewed along section S indicated in FIG. 1.

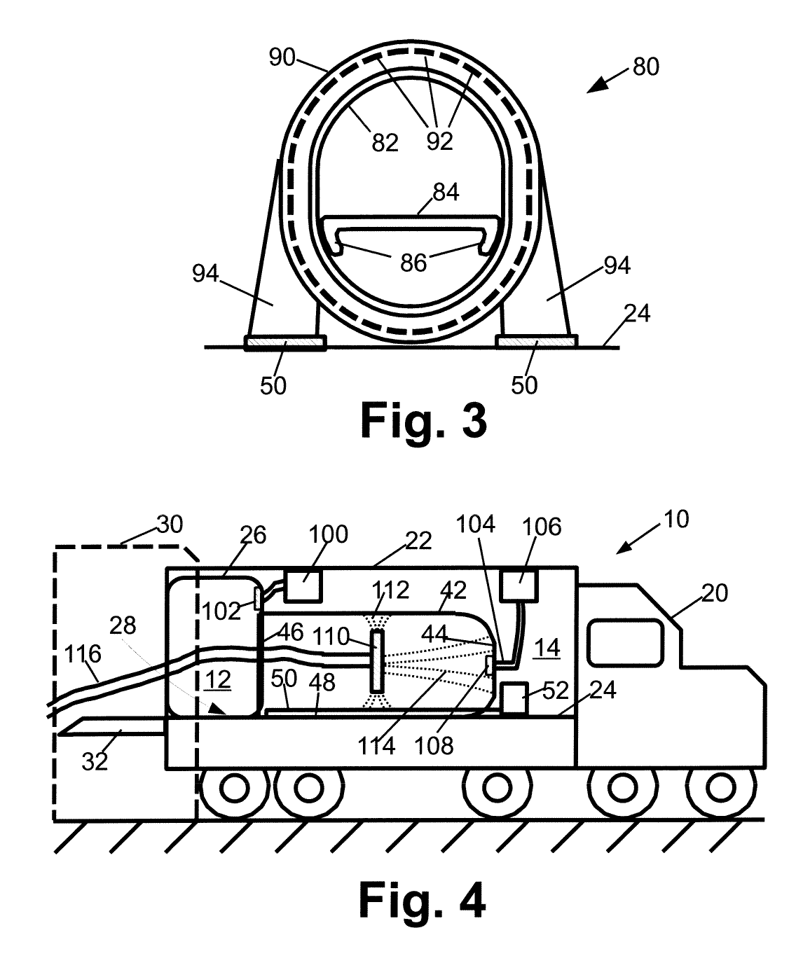

FIG. 3 diagrammatically shows a sectional view of the isolation tube of FIG. 1 and an alternative imaging apparatus embodied as an electron-beam computed tomography (CT) scanner, viewed along section S indicated in FIG. 1.

FIG. 4 diagrammatically shows decontamination of the isolation tube of the mobile imaging unit of FIG. 1.

With reference to FIG. 1, a mobile imaging unit includes a vehicle 10 having an interior that includes a contamination area 12 and an adjacent clean area 14. The term “contamination area” indicates an area in which biological or chemical contamination is allowed. However, the contamination area 12 is not necessarily contaminated at any given time. For example, the mobile imaging unit of FIG. 1 may be used to image a subject who is suspected of having been exposed to a biological or chemical contaminant, but may in fact not have been exposed. The clean area 14, on the other hand, is intended to be kept free of biological or chemical contamination even if contaminated subjects are imaged using the mobile imaging unit.

With reference to the illustrative mobile imaging unit of FIG. 1, the vehicle 10 includes a cab or tractor 20 and a trailer 22. The cab or tractor 20 provides motive force, steering and other capabilities that enable the vehicle 10 to be driven, while the trailer 22 provides a substantial interior for housing operative components of the mobile imaging unit. The cab 20 and trailer 22 can be separate, as for example in the case of a semi-trailer truck or tractor-trailer, or can be integrated as for example in the case of some panel trucks. Moreover, in other embodiments the vehicle may be of another type having sufficient interior space, such as a wagon, bus, or lorry.

A raised floor 24 is provided in the trailer 22 to provide a support surface for the contamination area 12 and the adjacent clean area 14. Although in the illustrated embodiment the raised floor 24 is continuous between the two areas 12, 14, it is also contemplated for the raised floor to have separate portions underlying the contamination area 12 and the adjacent clean area 14, respectively. It should be noted that the trailer 22 is enclosed by sidewalls, such that the raised floor 24 and other elements within the interior of the trailer 22 are not externally visible. However, for illustrative simplicity, in diagrammatic FIG. 1 the elements within the interior of the trailer 22 (such as the raised floor 24) are illustrated as if the righthand sidewall has been removed.

A contamination containment structure 26 defines the contamination area 12 and isolates it from the adjacent clean area 14. The illustrated contamination containment container 26 has a floor portion 28 that coincides with but does not include the raised floor 24. Alternatively, the contamination containment structure can incorporate a portion of the raised floor as part of the contamination containment structure. Similarly, the illustrated contamination containment structure 26 does not incorporate the sidewalls or top of the trailer 22, but in other embodiments the contamination containment structure optionally could incorporate the trailer sidewalls and/or top. An advantage of the illustrated contamination containment structure 26 which does not incorporate the raised floor 24 or trailer sidewalls or top is that the illustrated contamination containment container 26 can employ materials selected to promote contamination containment, such as molded plastic materials or the like, and can employ rounded interfaces between the floor, walls, and ceiling as illustrated for the contamination containment container 26 so as to promote ease of decontamination.

A subject is moved into the contamination area 12 for imaging. Toward this end, the mobile imaging unit is mobile and the vehicle 10 is suitably driven to the location of the subject. For example, in the event of an inadvertent release of a biological pathogen or toxic chemical, or a pandemic outbreak, the vehicle 10 is driven into or proximate to the contaminated location. If the vehicle is driven into a contaminated location, then the human driver operating the cab or tractor 20 is dressed in an isolation suit compatible with the known or suspected contamination level of the contaminated location. In other cases, the vehicle 10 may be driven proximate to, but not into a contaminated location, and the subject is then brought the rest of the way to the mobile imaging unit.

In the illustrated embodiment, the contaminated location is contained within a building or other stationary structure, and the vehicle 10 is driven to the building and backed toward the building so that the rear end of the trailer 22 can be docked with a stationary dock 30 (diagrammatically shown in phantom in FIG. 1) attached to the building so as to form a sealed connection between the stationary dock 30 and the contamination area 26. The dock 30 optionally may include a sealing ring or other sealing mechanism (not shown) to provide a sealed transfer pathway from the dock 30 into the contamination area 26 of the mobile imaging unit. In other embodiments, the stationary dock 30 may be a “makeshift” dock fabricated using a tarp, plastic sheeting, or other material that may be at hand.

Transfer of the subject from the stationary dock 30 or other contaminated location into the contamination area 12 of the trailer 22 can be done in various ways. In the illustrated embodiment, the trailer 22 includes a lift gate 32 that is configured to lift a subject gurney 34 from ground level to an elevated level at which the subject gurney can be wheeled onto the raised floor 24. In diagrammatic FIG. 1, the lift gate 32 is shown in the elevated level aligned with the raised floor 24, while the lift gate is shown in the ground level position in phantom view 32′. Instead of the illustrated lift gate 32, 32′, the stationary dock 30 can include an elevated dock platform having a height selected to be aligned with the raised floor 24 when the trailer 22 is docked. The subject gurney 34 is rolled from the lift gate 32 (or elevated dock platform) into the contamination area 12. The subject is typically a human subject or human cadaver, although an animal subject or an inanimate subject is also contemplated.

With continuing reference to FIG. 1 and with further reference to FIG. 2, the mobile imaging unit includes an imaging apparatus 40 for acquiring imaging data of the subject that is reconstructed into one or more images of the subject. FIG. 2 diagrammatically shows a sectional view of the isolation tube 42 and the imaging apparatus 40 of FIG. 1, viewed along section S indicated in FIG. 1. The imaging apparatus 40 is disposed in the clean area 14. To enable the subject to be moved into the imaging region of the imaging apparatus 40 while maintaining isolation, an isolation tube 42 extends into the clean area 14. The isolation tube has a closed end 44 and an opposite open end 46 that is open to a contamination area 12 adjacent the clean area 14 in order to receive the imaging subject from the contamination area 12. Isolation tubes are described generally, for example, in McKnight et al., U.S. Pat. Appl. No. 2008/0171935 A1 which is incorporated herein by reference in its entirety.

The illustrated isolation tube 42 is specially configured to facilitate ease of subject ingress and egress, to facilitate patient comfort, and to simplify isolation tube decontamination. Toward this end, a bottom 48 of the isolation tube coincides with the raised floor 24 such that the subject gurney 34 in the contamination area 12 can be wheeled from the raised floor 24 into the isolation tube 42. In other embodiments, the bottom of the isolation tube actually includes a portion of the raised floor, thus again enabling the gurney to be wheeled into the isolation tube. Advantageously, the imaging subject can be imaged on the gurney 34 which can be any general-purpose gurney so long as it is not made of a material that interferes with the imaging (for example, a magnetic material in the case of MR imaging, or a radiation-blocking material in the case of radiation emission or radiation transmission imaging modalities) and so long as it provides sufficient rigidity to avoid unacceptable subject motion during the imaging. The gurney 34 can, for example, be a patient gurney of the type used to transport patients from place to place, and can be as simple as a flat table or surface supported by legs having wheels or rollers or sliders. The subject supported by the gurney 34 is rolled into the isolation tube 42 via the opening 46. If the isolation tube 42 is too long for medical personnel to reach in so as to roll the gurney 34 into the imaging position, then a suitable pusher/pull rod, hook-on-a-stick or other implement can be used to extend their reach in order to load the gurney 34 into and out of the imaging position. Advantgeously, there is no need for a dedicated couch or patient support having an automatic mechanical translation mechanism.

In some instances, it may be desired to image a portion of the subject that is larger than the imaging region of the imaging apparatus 40. For example, a whole-body scan of a person lying in a prone position can be useful in order to detect lesions or other abnormalities anywhere in the body of the person—but, a typical MR scanner, CT scanner, or so forth does not have a field of view large enough to encompasss the entire subject while lying in a prone position. Conventionally, this is addressed by moving the subject through the imaging region either continuously while imaging, or in a step-wise fashion where the stopping points are imaging station positions at which imaging is performed with the subject stationary.

Instead of translating the subject as is conventionally done in medical imaging, the mobile imaging unit of FIGS. 1 and 2 employs the imaging apparatus 40 disposed in the clean area 14 which is movable along the isolation tube 42 in order to image a subject in the isolation tube 42 at a plurality of different positions along the isolation tube 42. Toward this end, the imaging apparatus 40 is mounted on rails 50. Mechanical translation of the imaging apparatus 40 along the isolation tube 42 is driven by a suitable drive motor 52 and gearing built into the rails 50, such as a worm gear (not shown). Although only floor-mounted rails 50 are illustrated, it is also contemplated to have additional rails mounted on the top or sidewalls of the trailer 22 to provide additional mechanical support for the movable imaging apparatus 40. Such additional rails may be passive support elements, or may include worm gears or other drive elements.

To perform multi-station imaging or continuous imaging, the subject gurney 34 suitably remains stationary while the imaging apparatus 40 is moved by the drive motor 52. Advantageously, this places the motion-generating machinery (e.g., the drive motor 52 and the worm gear or other drive mechanism) outside of the contamination area 12 and in the clean area 14, that is, outside of the area to be decontaminated.

With continuing reference to FIGS. 1 and 2, in one suitable embodiment the imaging apparatus 40 is a magnetic resonance (MR) scanner. The illustrated MR scanner has an open bore, and furthermore is oriented with north and south (or, alternatively, south and north) magnet poles 60, 62 disposed on opposing sides of the isolation tube 42. A ferromagnetic flux return path 64 is disposed above the isolation tube and connects the magnet poles. The components 60, 62, 64 form a magnet assembly that generates a static (B₀) magnetic field directed from the magnet pole 60 to the magnet pole 62 (as illustrated in FIG. 2) or vice versa, where the static (B₀) magnetic field is oriented generally transverse to the axis of the isolation tube 42. The magnet assembly 60, 62, 64 can employ either resistive or superconducting magnet windings.

The magnet assembly 60, 62, 64 is supported on support elements 66 configured to engage the floor-mounted rails 50 and the worm gear or other drive mechanism. If additional side- or top-mounted rails are provided, then additional support elements (not shown) can be included to secure the magnet assembly 60, 62, 64 with these additional rails. In the illustrated embodiment, the isolation tube 42 does not contribute to supporting the MR scanner 40, as indicated by a small gap between the magnet assembly 60, 62, 64 and the isolation tube 42 as seen in FIG. 2. However, if the isolation tube 42 is made of a sufficiently sturdy material, it is contemplated for the isolation tube 42 to contribute to supporting the MR scanner, and could even provide the total support for the

MR scanner. For example, it is contemplated to include rollers between the ferromagnetic flux return path 64 and the outer surface of the top of the isolation tube 42 such that the MR scanner could be rolled while supported by the isolation tube 42.

The MR scanner 40 further includes magnetic field gradient coils 68, 70 configured to selectively superimpose selected spatial magnetic field gradients on the static (B₀) magnetic field. Additionally, one or more radio frequency coils (not shown) are provided to excite and detect magnetic resonance (optionally spatially encoded using the magnetic field gradient coils 68, 70). The radio frequency coil or coils can be disposed outside the isolation tube 42, for example mounted as an assembly with the magnet poles 60, 62 and gradient coils 68, 70. Additionally or alternatively, one or more radio frequency coils can be disposed inside the isolation tube 42. In this latter arrangement, the radio frequency coil or coils is optionally wireless such that it conveys signals and, optionally, electrical power, wirelessly through the isolation tube 42. Any radio frequency coil disposed inside the isolation tube 42 is therefore in the contamination area 12, and accordingly is preferably housed in a hermetically sealed housing preferably having smooth outer surfaces to facilitate ease of decontamination of the coil. Further components that are not illustrated can also be included. For example, one or more radio frequency screens may be included to constrain the generated radio frequency fields. For the illustrated embodiment in which the imaging apparatus 40 is an MR scanner, the trailer 22 is preferably shielded to define a “shielded room” substantially enclosing the MR scanner 40 to prevent radio frequency interference with or generated by the MR scanner 40.

The illustrated MR scanner 40 does not extend below the raised floor 24. This simplifies movement of the MR scanner 40 along the rails 50 and facilitates arranging the bottom 48 of the isolation tube coincident with the raised floor 24 such that the subject gurney 34 in the contamination area 12 can be wheeled from the raised floor 24 into the isolation tube 42. Although the MR scanner 40 does not extend below the raised floor 24, electronics 72 for powering or operating the imaging apparatus 40 are optionally disposed on or in the vehicle 10 below the raised floor 24, and are connected with the scanner MR scanner 40 by flexible cabling that permits movement of the scanner 40 along the rails 50. In some embodiments, the electronics 72 are accessible from underneath the vehicle 10 for maintenance or replacement. Optionally other stationary components, such as the drive motor 52, are also placed under the raised floor 24.

Optionally, the electronics 72 may include control electronics for implementing a desired imaging data acquisition pulse sequence or other imaging apparatus control routines. Optionally, the electronics 72 may include data processing electronics such as an image reconstruction processor programmed to employ a suitable reconstruction algorithm to reconstruct the acquired magnetic resonance data to generate an image. Resulting images can be displayed on a computer or monitor (not shown) disposed in the clean area 14, or can be wirelessly transmitted to a remote location where medical peronnel can view the images at a safe distance from the contaminated location. In some embodiments, the electronics 72 include a computer or other suitable electronic device including a digital processor programmed to perform desired control and/or data processing operations. Optionally, the electronics 72 may include other components such as gradient coil power supplies, radio frequency transmit and/or receive electronics, and so forth. These electronics may be disposed beneath the raised floor 24 as shown in FIG. 1, or may be disposed in the clean area 14 on or above the raised floor 24, or may be apportioned between above/below floor locations.

With reference to FIG. 3, the imaging apparatus can be other than the MR scanner 40 of FIGS. 1 and 2. For example, FIG. 3 illustrates a sectional view of the isolation tube, viewed along section S indicated in FIG. 1, with an alternative imaging apparatus 80 comprising an electron beam computed tomography (e-beam CT) scanner 80. As noted previously, the MR scanner 40 is configured to have an inverted “U” shape to accommodate making the bottom 48 of the isolation tube coincident with the raised floor 24. In contrast, a CT scanner employs tomographic imaging in which a radiation beam rotates a full 360° around the subject. A similar issue arises with a positron emission tomography (PET) scanner (not illustrated) where a full annular ring extending 360° around the subject is generally used to acquire complete tomographic data. To accommodate radiation beam rotation a full 360° around the subject, the isolation tube 42 is replaced in the embodiment of FIG. 3 by an isolation tube 82 having a bottom that does not coincide with the raised floor 24. Rather, the isolation tube 82 has a rounded bottom that is elevated respective to the raised floor 24. This arrangement is similar to isolation tubes described in McKnight et al., U.S. Pat. Appl. No. 2008/0171935 A1 which is incorporated herein by reference in its entirety, and indeed the isolation tube 82 may be identical with isolation tubes disclosed in McKnight et al.

Since the gurney 34 cannot be rolled into the elevated isolation tube 82, another subject support mechanism is employed. In the embodiment illustrated in FIG. 3, a sliding subject support table 84 is used, which has contoured sides 86 that dovetail with the sides of the isolation tube 82 such that the support table 84 is supported by the isolation tube 82. An advantage of the subject support table 84 is that it is mechanically simple, having no moving parts, and has rounded edges that facilitate ease of decontamination. However, other support arrangements are also contemplated, such as a cantilevered support or other support disclosed in U.S. Publ. Appl. No. 2008/0173218 A1 which is incorporated herein by reference in its entirety.

The e-beam CT scanner 80 includes a generally annular evacuated housing 90 containing an annular anode or annular assembly of anode elements 92 arranged around the isolation tube 82. An electron beam source (not shown) is arranged to generate and steer an electron beam to irradiate the annular anode or annular assembly of anode elements 90 so as to generate an x-ray beam that rotates around the isolation tube 82. Some suitable e-beam CT scanners are disclosed, for example, in Boyd et al., U.S. Pat. No. 4,352,021 and Schomberg, U.S. Publ. Appl. No. 2007/0165773 A1, both of which are incorporated herein by reference in their entireties. Support elements 94 support the e-beam CT scanner 80 and engage the rails 50.

A conventional CT scanner employs a rotating x-ray tube that rotates around the subject at a high rate of speed, for example at 60 revolutions per minute, or 10 revolutions per minute, or faster. The illustrated e-beam CT scanner 80 has an advantage over a conventional CT scanner in that it does not have a rapidly rotating x-ray tube. This simplifies movement of the e-beam CT scanner 80 along the isolation tube 82 via the rails 50. However, it is also contemplated to employ a conventional CT scanner in place of the illustrated e-beam CT scanner 80. Moreover, other imaging modalities (not illustrated), such as a PET scanner, a gamma camera for acquiring single photon emission computed tomography (SPECT) imaging data, or so forth are also contemplated, as each of these can be suitably mounted on the rails 50.

The illustrated e-beam CT scanner 80 does not extend below the raised floor 24. However, it is also contemplated to allow the imaging apparatus to extend below the raised floor 24, for example by including a groove or slot in the raised floor to accommodate the portion of the imaging apparatus that extends below the raised floor as it moves along the rails 50.

With returning reference to FIG. 1, an optional camera 96 is disposed in the clean area 14 with the imaging apparatus 40, and is used to align the imaging area with the subject disposed in the isolation tube 42. The camera 96 may, for example, be a charge coupled device (CCD) camera imaging in the visible or infrared spectrum. The illustrated optional camera 96 is mounted on the ferromagnetic flux return path 64 of the MR scanner 40 and accordingly moves together with the imaging apparatus 40 as the latter moves along the rails 50. The camera 96 images the subject along a viewing path V that is offset by a distance d along the isolation tube 42 from a center of the imaging region of the imaging apparatus 40. To enable imaging, the isolation tube 42 (or a portion coinciding with the viewing path V) should be transparent over at least a portion of a visible or infrared wavelength range that is imaged by the camera 96. The offset distance d is known and does not change as the MR scanner 40 and attached camera 96 move together. Accordingly, the center of the imaging region can be determined based on the image produced by the camera 96 and the known distance offset d. In some embodiments, an initial prescan is performed which acquires imaging information using the camera 96 and, optionally, also using the imaging apparatus 40. Alternatively, no prescan can be obtained, but instead imaging progresses with the MR scanner 40 and attached camera 96 moving toward the left (as shown in FIG. 1) such that the camera 96 acquires an image of the subject or portion of the subject at a time d/velocity before the MR scanner 40 imaging region is centered at the same location (where “velocity” is the velocity at which the MR scanner 40 moves along the rails 50). For a stationary image acquisition, once the camera 96 is centered over the location to be imaged the imaging apparatus 40 is moved the further distance d in the leftward direction (again, using the FIG. 1 coordinates) in order to center the imaging region of the imaging apparatus 40 at the location to be imaged.

With reference to FIG. 4, the mobile imaging unit of FIG. 1 is illustrated with the imaging apparatus 40 removed, and FIG. 4 is referenced in describing the air handling and decontamination systems of the mobile imaging unit. The contamination area 12 is maintained under a slight negative pressure respective to atmosphere by a pump 100 that draws air out of the contamination area 12 via a high efficiency particulate air (HEPA) filter 102 that ensures that the pump 100 does not draw in biological or particulate chemical contamination from the contamination area 12 if any such contamination is present.

The isolation tube 42 (or, alternatively, the isolation tube 82 illustrated in FIG. 3) presents a location prone to air stagnation, which can be detrimental both from the standpoint of accumulating any contamination that may be present in the isolation tube, and from the standpoint of comfort of the subject loaded in the isolation tube. Optionally, an air inlet port 104 disposed at the closed end 44 of the isolation tube 42 outputs air in order to maintain air flow from the closed end 44 of the isolation tube 42 to the open end 46. An air pump 106 delivers air to the air inlet port 104. Optionally, a HEPA filter 108 is arranged to filter air passing through the air inlet port 104 disposed at the closed end 44 of the isolation tube 42. The air flow delivered by the air inlet port 104 (and thence into the contamination area 12) should be low enough to ensure that the contamination area 12 remains under slight negative pressure. This is suitably achieved by balancing the operation of the two pumps 100, 106 until desired air flow and air pressure readings are obtained using air flow and air pressure sensors (not shown).

With continuing reference to FIG. 4, decontamination of the contamination area 12 and the inside of the isolation tube 42 (or, equivalently, the isolation tube 82 shown in FIG. 3) is suitably performed using a spray head 110 arranged for insertion in the isolation tube 42 and configured to output an annular pattern 112 of fluid spray for decontaminating the walls of the isolation tube 42. Optionally, an additional forward spray pattern 114 is directed forward for decontaminating the closed end 44 of the isolation tube 42. The fluid can be water, a solvent, or other liquid or gaseous fluid that is capable of removing biological or particulate chemical contamination. For biological contamination, the fluid optionally includes an antiseptic agent that kills the biological pathogen. The fluid is suitably delivered by a hose 116 that passes through the open end 46 of the isolation tube 42. The isolation tube 42 and contamination area 12 preferably have smooth sides and rounded corners or rounded interfaces between walls, floor, and ceiling so that the fluid spray 112, 114 can readily reach and decontaminate all inside surfaces of the isolation tube 42. The gurney 34 can be removed entirely for decontamination, or can be decontaminated while in the contamination area 12 using the spray head 110 or another decontamination approach. Advantageously, the gurney 34 is not complex, that is, does not include an automated translation mechanism or other complexity that might make decontamination difficult. In the embodiment of FIG. 3, the support table 84 can similarly be removed to the contamination area 12 or entirely outside of the mobile imaging unit for decontamination, and also has rounded corners to avoid trapping contaminants

This application has described one or more preferred embodiments. Modifications and alterations may occur to others upon reading and understanding the preceding detailed description. It is intended that the application be construed as including all such modifications and alterations insofar as they come within the scope of the appended claims or the equivalents thereof.

1. A system comprising:
an isolation tube extending into a clean area, the isolation tube having a closed end and an opposite open end that is open to a contamination area adjacent the clean area in order to receive an imaging subject from the contamination area; and
an imaging apparatus disposed in the clean area and movable along the isolation tube in order to image a subject in the isolation tube at a plurality of different positions along the isolation tube.

2. The system as set forth in claim 1, wherein the imaging apparatus is configured to perform multi-station imaging at a plurality of different position stations along the isolation tube.

3. The system as set forth in claim 1, wherein the imaging apparatus is configured to perform continuous imaging as the imaging apparatus is moved continuously along the isolation tube.

4. The system as set forth in claim 1, further comprising:
a vehicle having an interior including the contamination area and the adjacent clean area wherein the system is a mobile imaging unit.

5. The system as set forth in claim 4, further comprising:
a raised floor disposed in the vehicle and supporting the imaging apparatus.

6. The system as set forth in claim 5, wherein the imaging apparatus does not extend below the raised floor.

7. The system as set forth in claim 6, wherein the imaging apparatus comprises:
an open magnetic resonance scanner including magnet poles disposed on opposing sides of the isolation tube and a ferromagnetic flux return path disposed above the isolation tube and connecting the magnet poles.

8. The system as set forth in claim 1, wherein the imaging apparatus comprises:
an electron beam computed tomography (e-beam CT) scanner including an annular anode or annular assembly of anode elements arranged around the isolation tube .

9. The system as set forth in claim 1, further comprising:
a camera disposed in the clean area and mounted to move along the isolation tube with the imaging apparatus in order to image a subject in the isolation tube at a predetermined offset distance along the isolation tube respective to an imaging region of the imaging apparatus.

10. An imaging method performed using the system of claim 1, the imaging method comprising:
transferring a subject from the contamination area into the isolation tube via the open end of the isolation tube;
acquiring imaging data of the subject using the imaging apparatus with the imaging apparatus positioned at a plurality of successive different positions along the isolation tube; and
reconstructing the imaging data of the subject to generate one or more reconstructed images of the subject.

11. The imaging method as set forth in claim 10, wherein the system is a mobile imaging unit further comprising a vehicle having an interior including the contamination area and the adjacent clean area, the imaging method further comprising:
driving the vehicle to a location of a subject; and
after the driving, moving the subject into the contamination area.

12. The imaging method as set forth in claim 11, wherein the moving comprises:
docking the vehicle with a stationary dock so as to form a connection between the stationary dock and the contamination area.

13. The imaging method as set forth in claim 11, further comprising:
after the acquiring, transferring a subject from the isolation tube back to the contamination area via the open end of the isolation tube; and
decontaminating the isolation tube by spraying the isolation tube with a cleaning fluid delivered via a hose passing through the open end of the isolation tube.

14. A system comprising:
an isolation tube extending into a clean area, the isolation tube having a closed end and an opposite open end that is open to a contamination area adjacent the clean area in order to receive an imaging subject from the contamination area; and
an imaging apparatus disposed in the clean area to image a subject in the isolation tube; and
an air inlet port disposed at the closed end of the isolation tube to maintain air flow from the closed end to the open end.

15. The system as set forth in claim 14, further comprising:
a high efficiency particulate air (HEPA) filter arranged to filter air passing through the air inlet port disposed at the closed end of the isolation tube.

16. The system as set forth in claim 14, further comprising:
a spray head arranged for insertion in the isolation tube and configured to output an annular pattern of fluid spray.

17. The system as set forth in claim 14, further comprising:
a vehicle having an interior including the contamination area and the adjacent clean area wherein the system is a mobile imaging unit.

18. A system comprising:
an isolation tube extending into a clean area, the isolation tube having a closed end and an opposite open end that is open to a contamination area adjacent the clean area in order to receive an imaging subject from the contamination area;
an imaging apparatus disposed in the clean area to image a subject in the isolation tube;
a vehicle having an interior including the contamination area and the adjacent clean area wherein the system is a mobile imaging unit; and
a raised floor disposed in the vehicle and supporting the imaging apparatus.

19. The system as set forth in claim 18, wherein the imaging apparatus does not extend below the raised floor.

20. The system as set forth in claim 19, wherein the imaging apparatus comprises:
an open magnetic resonance scanner including magnet poles disposed on opposing sides of the isolation tube and a ferromagnetic flux return path disposed above the isolation tube and connecting the magnet poles.

21. The system as set forth in claim 18, wherein a bottom of the isolation tube coincides with the raised floor or includes a portion of the raised floor such that a subject gurney in the contamination area can be wheeled from the raised floor into the isolation tube.

22. The system as set forth in claim 21, wherein the bottom of the isolation tube joins with sides of the isolation tube via a rounded interface and the top of the isolation tube is rounded or joins with the sides of the isolation tube via rounded interfaces.

23. The system as set forth in claim 18, further comprising:
electronics for powering or operating the imaging apparatus, the electronics being disposed on or in the vehicle below the raised floor.

24. The system as set forth in claim 18, further comprising:
a contamination containment structure that defines the contamination area, the contamination containment structure having a floor portion that coincides with but does not include the raised floor.

25. The system as set forth in claim 18, further comprising:
a lift gate configured to lift a subject gurney from ground level to an elevated level at which the subject gurney can be wheeled onto the raised floor.

26. The system as set forth in claim 18, further comprising:
an air inlet port disposed at the closed end of the isolation tube to maintain air flow from the closed end to the open end.
